(19) United States
(12) Patent Application Publication
(10) Pub. No.: US 2025/0169287 A1
(43) Pub. Date: May 22, 2025

(54) Display Device

(71) Applicant: LG Display Co., Ltd., Seoul (KR)

(72) Inventor: Hwangun Seo, Paju-si (KR)

(21) Appl. No.: 18/760,983

(22) Filed: Jul. 1, 2024

(30) Foreign Application Priority Data
Nov. 21, 2023 (KR) 10-2023-0162100

(51) Int. Cl. H10K 59/122; H10K 50/19; H10K 59/12; H10K 102/00

(52) U.S. Cl. CPC H10K 59/122; H10K 50/19; H10K 59/1201; H10K 2102/351

(57) ABSTRACT

A display device includes a substrate having a pixel including a plurality of sub-pixels, a first electrode disposed in each of the plurality of sub-pixels, and a bank disposed between adjacent sub-pixels on the first electrode, wherein the first electrode of a second sub-pixel among the plurality of sub-pixels is positioned under the first electrode of a first sub-pixel, and the bank includes a plurality of side surfaces, and lengths between the side surfaces are different.

### CROSS REFERENCE TO RELATED APPLICATION

The present application claims priority to Republic of Korea Patent Application No. 10-2023-0162100, filed on Nov. 21, 2023, which is hereby incorporated by reference in its entirety.

### BACKGROUND

### Field of Technology

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED display devices as the self-luminous types have superior viewing angles and contrast ratios than the LCD devices, and are lighter and thinner and have low power consumption because they do not require a separate backlight. In addition, there is an advantage in that the OLED display devices may drive at a low DC voltage, have a fast response time, and especially low manufacturing costs.

Recently, demand for displays requiring augmented reality (AR), virtual reality (VR) or equivalent ultra-high resolution using an OLED display device is increasing.

Meanwhile, the common emission layer of the OLED display device includes a conductive charge generation layer. When the charge generation layer is formed integrally in a red sub-pixel, a green sub-pixel, and a blue sub-pixel, color mixing may occur between the sub-pixels.

### SUMMARY

The present invention is directed to providing a display device which can implement ultra-high resolution by forming transistors on an insulating layer without separately depositing the transistors on a substrate, and depositing the insulating layer on which the transistors are formed on the substrate when the display device is manufactured.

The present disclosure is also directed to providing a display device which can improve the occurrence of light color mixing between adjacent sub-pixels in a method of inducing the disconnection of a charge generation layer by forming the charge generation layer in a smaller thickness in the adjacent sub-pixels.

The present disclosure is also directed to providing a display device which can improve the occurrence of light color mixing between the adjacent sub-pixels by separating the charge generation layer in the adjacent sub-pixels.

The objects of the present specification are not limited to the above-described object, and other technical objects may be inferred from embodiments below.

To achieve the objects, a display device according to one embodiment includes a substrate having a pixel including a plurality of sub-pixels, a first electrode disposed in each of the plurality of sub-pixels, and a bank disposed between adjacent sub-pixels on the first electrode, wherein the first electrode of a second sub-pixel among the plurality of sub-pixels is positioned under the first electrode of a first sub-pixel, and the bank includes a plurality of side surfaces, and lengths between the side surfaces are different.

To achieve the objects, a display device according to another embodiment includes a substrate having a pixel including a plurality of sub-pixels, a first electrode disposed in each of the plurality of sub-pixels, a bank disposed between adjacent sub-pixels on the first electrode, and a common emission layer disposed on an upper surface of the first electrode exposed by the bank and the bank, wherein the bank has an asymmetric shape, and at least one of the common emission layers is separated from the bank with the asymmetric shape.

Detailed matters of other embodiments are included in a detailed description and accompanying drawings.

According to the embodiments, when the display device is manufactured, it is possible to implement ultra-high resolution by forming the transistors on the insulating layer without separately depositing the transistors on a substrate, and depositing the insulating layer on which the transistors are formed on the substrate when the display device is manufactured.

In addition, in adjacent sub-pixels, by forming the indentation in the insulating layer and positioning the first electrode positioned in the indentation under the first electrode not positioned in the indentation, the lengths of the side surfaces of the bank formed on each first electrode can be adjusted differently.

The common emission layer including the thin charge generation layer may be disposed on the bank, and the charge generation layer can become thinner at the side surface with the longer bank and thus be separated.

Therefore, it is possible to prevent or at least reduce the occurrence of light color mixing between the adjacent sub-pixels.

However, the effects obtainable from the present specification are not limited to the above-described effects, and other effects that are not mentioned will be able to be clearly understood by those skilled in the art to which the present specification pertains from the following description.

### BRIEF DESCRIPTION OF THE DRAWINGS

FIG. 1 is a plan view of a display device according to one embodiment.

FIG. 2 is a cross-sectional view of the display device along line A-A′ in FIG. 1 according to one embodiment.

FIG. 3 is a cross-sectional view of an organic light emitting diode (OLED) according to FIG. 2 according to one embodiment.

FIG. 4 is a cross-sectional view of an OLED according to a modified example of FIG. 2 according to one embodiment.

FIG. 5 is an enlarged view of area Q1 in FIG. 2 according to one embodiment.

FIG. 6 is an enlarged view of area Q2 in FIG. 5 according to one embodiment.

FIG. 7 is an enlarged view of area Q2 of the display device of FIG. 5 according to the modified example.

FIGS. 8 to 18 are cross-sectional views for each process in a method of manufacturing the display device according to one embodiment.

FIG. 19 is an enlarged view of area Q2 of the display device of FIG. 5 according to another embodiment.

FIG. 20 is an enlarged view of area Q2 of the display device of FIG. 5 according to still another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

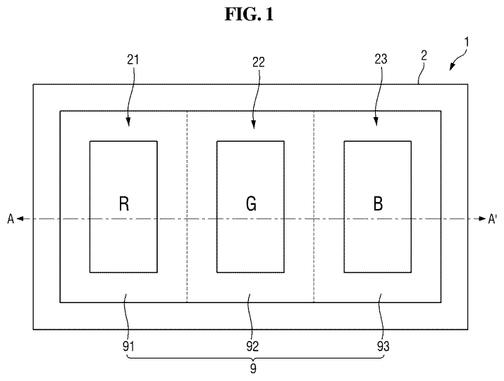

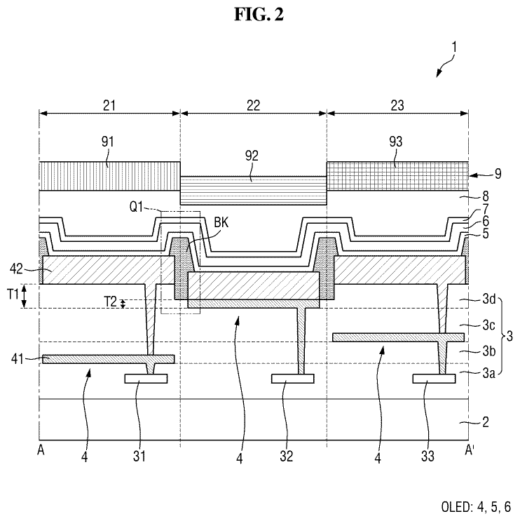

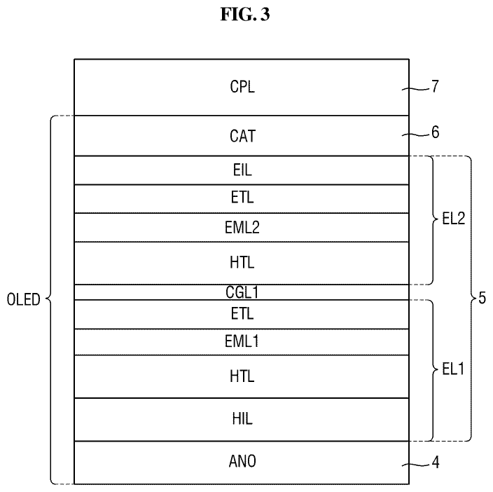

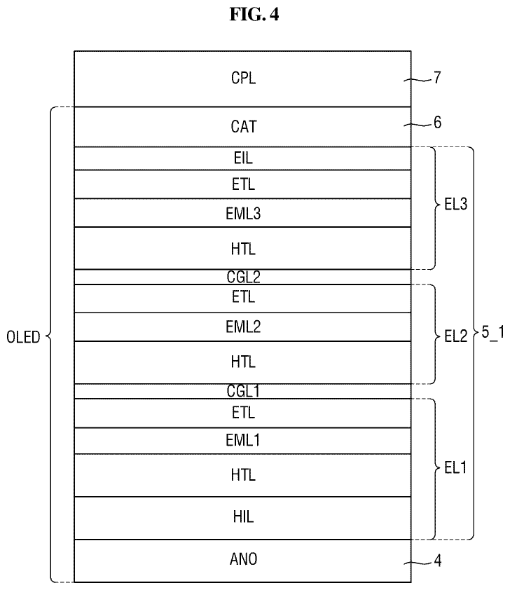

FIG. 1 is a plan view of a display device according to one embodiment. FIG. 2 is a cross-sectional view of the display device along line A-A′ in FIG. 1 according to one embodiment. FIG. 3 is a cross-sectional view of an organic light emitting diode (OLED) according to FIG. 2 according to one embodiment. FIG. 4 is a cross-sectional view of an OLED according to a modified example of FIG. 2 according to one embodiment.

Referring to FIGS. 1 to 4, a display device 1 according to one embodiment includes a substrate 2, a first electrode 4, a bank BK, a common emission layer 5, and a second electrode 6.

A plurality of sub-pixels 21, 22, and 23 are formed on the substrate 2. Also, more or less sub-pixels may be formed on the substrate 2. The plurality of sub-pixels 21, 22, and 23 may form one pixel. The plurality of pixels may be formed on the substrate 2.

The plurality of sub-pixels 21, 22, and 23 include the first sub-pixel 21, the second sub-pixel 22, and the third sub-pixel 23. Since the first sub-pixel 21, the second sub-pixel 22, and the third sub-pixel 23 may be disposed sequentially, the second sub-pixel 22 may be disposed adjacent to one side, for example, the left side of the first sub-pixel 21, and the third sub-pixel 23 may be disposed adjacent to one side, for example, the left side of the second sub-pixel 22. As one example, the second sub-pixel 22 may be disposed between the first sub-pixel 21 and the third sub-pixel 23, without being limited thereto.

Throughout the present specification, when two sub-pixels are disposed adjacent to each other, it should be construed to mean that no other sub-pixels are disposed between the two sub-pixels.

Although the first sub-pixel 21 may be provided to emit red (R) light, the second sub-pixel 22 may be provided to emit blue (B) light, and the third sub-pixel 23 may be provided to emit green (G) light, the present disclosure is not necessarily limited thereto. Alternatively, the sub-pixels 21, 22, and 23 can be implemented to emit light of other color such as cyan, magenta, or yellow, etc.

Although FIG. 1 shows that the pixel includes only three sub-pixels 21, 22, and 23, the present disclosure is not limited thereto, and the pixel may include four sub-pixels. When the pixel includes four sub-pixels, the pixel may further include a fourth sub-pixel provided to emit white (W) light.

Each of the first to third sub-pixels 21, 22, and 23 may be provided to have the same size. For example, each of the first to third sub-pixels 21, 22, and 23 may be provided to have the same width and the same height. Here, although the width may indicate a horizontal direction based on FIG. 1, and the height may indicate a direction perpendicular to the width based on FIG. 1, the present disclosure is not necessarily limited thereto.

The bank BK may be disposed between the first sub-pixel 21, the second sub-pixel 22, and the third sub-pixel 23. The bank BK according to one embodiment is used to distinguish the first sub-pixel 21, the second sub-pixel 22, and the third sub-pixel 23.

The bank BK serves to define a sub-pixel. Thus, the bank BK may be made of an insulating material containing a black material. The bank BK may be made of, for example, a transparent carbon-based mixture. Specifically, the bank BK may contain carbon black, but is not limited thereto. The bank BK may also be made of a transparent insulating material.

The first electrode 4 is patterned for each of the sub-pixels 21, 22, and 23. In other words, one first electrode 4 is formed in the first sub-pixel 21, another first electrode 4 is formed in the second sub-pixel 22, and the remaining first electrode 4 is formed in the third sub-pixel 23. The first electrode 4 may function as an anode of the display device 1. The bank BK may be provided to cover an edge of the first electrode 4 disposed in each of the first to third sub-pixels 21, 22, and 23 to distinguish the first sub-pixel 21, the second sub-pixel 22, and the third sub-pixel 23. Therefore, an emission area can be defined by the bank BK.

In the display device, the first electrode 4 may be provided as a plurality of layers including a reflective layer 41, thereby further increasing light extraction efficiency using the micro cavity characteristic.

The micro cavity characteristic indicates a characteristic that when a distance between the reflective layer 41 and the second electrode 6 is an integer multiple of a half wavelength (λ/2) of light emitted from the sub-pixel, constructive interference occurs to amplify the light, and when a reflection and re-reflection process is repeated between the reflective layer 41 and the second electrode 6, the degree of amplified light continuously increases, thereby increasing the external extraction efficiency of light.

The common emission layer 5 may be provided to emit white light. For example, the common emission layer 5 may be provided to emit white light by being provided in a two-stack structure including a blue emission layer, a yellow-green emission layer, and a charge generation layer or is provided in a three-stack structure including the blue emission layer, a green emission layer, a red emission layer, and the charge generation layer, but is not necessarily limited thereto, and may be provided in a plurality of layers exceeding 3 stacks as long as it may emit white light.

The common emission layer 5 may be formed as a common layer throughout all of the first to third sub-pixels 21, 22, and 23. Therefore, the common emission layer 5 may cover the first electrode 4 disposed in each sub-pixel and the bank BK disposed between the sub-pixels. However, the charge generation layer of the common emission layer 5 may have conductivity. Therefore, when the charge generation layer of the common emission layer 5 is consecutively disposed throughout all of the first to third sub-pixels 21, 22, and 23, light color mixing may occur at boundaries of the adjacent first to third sub-pixels 21, 22, and 23. Therefore, in the case of the display device 1 according to one embodiment, the charge generation layer of the common emission layer 5 may be separated at one or more of the boundaries of the adjacent first to third sub-pixels 21, 22, and 23. Detailed description thereof will be made below.

The second electrode 6 is used to form an electric field with the first electrode 4 and may function as a cathode. The second electrode 6 may be disposed on an upper surface of the common emission layer 5, which is opposite to a lower surface of the common emission layer 5 with which the first electrode 4 is in contact, and provided as a common layer throughout the first to third sub-pixels 21, 22, and 23.

Each of the first electrode 4 and the second electrode 6 may comprise a metal material such as Au, W, Pt, Si, Ir, Ag, Cu, Ni, Ti, or Cr, and an alloy thereof. Alternatively, each of the first electrode 4 and the second electrode 6 may include a transparent conductive material such as ITO indium tin oxide or IZO indium zinc oxide, without being limited thereto.

In the case of the top emission type, the second electrode 6 may be provided as a transparent electrode, and in the case of the bottom emission type, the second electrode 6 may be provided as an opaque electrode including a reflective material. In the case of the top emission type, the second electrode 6 may be formed as a translucent electrode to increase light extraction efficiency using the micro cavity characteristic. Since the display device increases light extraction efficiency using the micro cavity characteristic in the top emission type, an example in which the second electrode 6 is formed as the translucent electrode will be described.

The color filter layer 9 is provided in each of the first to third sub-pixels 21, 22, and 23 to block a specific color from light emitted from the emission layer of each sub-pixel. A first color filter 91 provided in the first sub-pixel 21 may be provided to block light of other colors excluding red (R) light. In this case, the first color filter 91 may be provided as a red color filter. A second color filter 92 provided in the second sub-pixel 22 may be provided to block light of other colors excluding blue (B) light. In this case, the second color filter 92 may be provided as a blue color filter. A third color filter 93 provided in the third sub-pixel 23 may be provided to block light of other colors excluding green (G) light. In this case, the third color filter 93 may be provided as a green color filter. However, the present specification is not necessarily limited thereto.

The first to third color filters 91, 92, and 93 provided in the first to third sub-pixels 21, 22, and 23, respectively may be provided in the same size as each sub-pixel or provided by being reduced or enlarged at a constant ratio with respect to each sub-pixel.

Hereinafter, the stacked structure of the display device 10 according to one embodiment will be described in detail.

The display device 1 according to one embodiment includes the substrate 2, the insulating layer 3, the first electrode 4, the bank BK, the common emission layer 5, the second electrode 6, a capping layer 7, an encapsulation layer 8, and the color filter layer 9.

The substrate 2 may be a plastic film, a glass substrate, or a semiconductor substrate such as silicon or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The substrate 2 may be made of a transparent material or an opaque material. The first sub-pixel 21, the second sub-pixel 22, and the third sub-pixel 23 are provided on the substrate 2. The first sub-pixel 21 may be provided to emit red (R) light, the second sub-pixel 22 may be provided to emit blue (B) light, and the third sub-pixel 23 may be provided to emit green (G) light without being limited thereto. Alternatively, the sub-pixels 21, 22, and 23 can be implemented to emit light of other color such as cyan, magenta, or yellow, etc.

The display device 1 according to one embodiment is configured in a so-called top emission type in which the emitted light is emitted upward, and thus a material of the substrate 100 may include not only a transparent material but also an opaque material. The color filters 91, 92, and 93 may be respectively provided above the first to third sub-pixels 21, 22, and 23 from which light is emitted to transmit light of the same color.

The insulating layer 3 is formed on the substrate 2. The insulating layer 3 may include a plurality of stacked insulating layers 3a, 3b, 3c, and 3d. The insulating layers 3a, 3b, 3c, and 3d according to one embodiment may be sequentially stacked in a thickness direction and may include the same material. However, the present specification is not limited thereto, and the insulating layers 3a, 3b, 3c, and 3d may include different materials. The insulating layer 3 is provided with circuit elements including a plurality of thin film transistors 31, 32, and 33, various signal lines, capacitors, and the like for each sub-pixel 21, 22, and 23. The signal lines may include a gate line, a data line, a power line, and a reference line, and the thin film transistors 31, 32, and 33 may include a switching thin film transistor, a driving thin film transistor, and a sensing thin film transistor. Each of the sub-pixels 21, 22, and 23 is defined by an intersection structure of gate lines and data lines.

The switching thin film transistor functions to supply the data voltage supplied from the data line to the driving thin film transistor by being switched according to a gate signal supplied to the gate line.

The driving thin film transistor functions to generate and supply a data current from the power supplied from the power line to the first electrode 4 by being switched according to the data voltage supplied from the switching thin film transistor.

The sensing thin film transistor functions to sense a threshold voltage deviation of the driving thin film transistor, which causes the degradation of image quality, and supplies the current of the driving thin film transistor to the reference line in response to a sensing control signal supplied from the gate line or a separate sensing line.

The capacitor functions to maintain the data voltage supplied to the driving thin film transistor for one frame and is connected to each of a gate terminal and a source terminal of the driving thin film transistor.

The first transistor 31, the second transistor 32, and the third transistor 33 are disposed for each individual sub-pixel 21, 22, and 23 in the first insulating layer 3a. The first transistor 31 according to one embodiment may be connected to the first electrode 4 disposed on the first sub-pixel 21 to apply a driving voltage for emitting light of a color corresponding to the first sub-pixel 21.

The second transistor 32 according to one embodiment may be connected to the first electrode 4 disposed on the second sub-pixel 22 to apply a driving voltage for emitting light of a color corresponding to the second sub-pixel 22.

The third transistor 33 according to one embodiment may be connected to the first electrode 4 disposed on the first sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 according to one embodiment supplies a predetermined current to the emission layer according to the data voltage of the data line. Therefore, the emission layer of each of the first sub-pixel 21, the second sub-pixel 22, and the third sub-pixel 23 may emit light with a predetermined brightness according to the predetermined current. For example, the emission layer may include one or more of a hole injection layer (HIL), a hole transmitting layer (HTL), an electron transmitting layer (ETL) and an electron injection layer (EIL), but the present disclosure is not limited thereto.

The first insulating layer 3a may protect the transistors 31, 32, and 33. The first insulating layer 3a may be made of an organic insulating material, but is not necessarily limited thereto and may be made of an inorganic insulating material. The transistors 31, 32, and 33 may be positioned in the first insulating layer 3a.

The first electrode 4 of the first sub-pixel 21 or the reflective layer to be described below may be disposed on the first insulating layer 3a.

The first electrode 4 is patterned for each of the first to third sub-pixels 21, 22, and 23. The first electrode 4 is connected to the driving thin film transistor provided in the insulating layer 3. Specifically, the first electrode 4 is connected to the source terminal or the drain terminal of the driving thin film transistor. To this end, a contact hole for exposing the source terminal or the drain terminal of the driving thin film transistor is formed in the insulating layer 3, and the first electrode 4 is connected to the source terminal or the drain terminal of the driving thin film transistor through the contact hole.

The display device 1 according to one embodiment may be provided in the top emission type, and to this end, the first electrode 4 may be provided to reflect light emitted from the common emission layer 5 upward. In this case, the first electrode 4 may be formed in a double layer structure of the reflective layer 41 (or a reflective electrode or a reflector) for reflecting light, and a transparent layer 42 (or a transparent electrode, an ITO electrode, or an anode) for supplying holes to the common emission layer 5.

The reflective layer 41 may reflect the light emitted toward the reflective layer 41 among the light emitted from the common emission layer 5 of each of the sub-pixels 21, 22, and 23 toward the second electrode 6 or the encapsulation layer 8. In addition, the reflective layer 41 is used to implement the micro cavity characteristic through reflection and re-reflection with the second electrode 6. To this end, the reflective layer 41 may include a reflective material for reflecting light. For example, the reflective material may be a metal, but is not necessarily limited thereto and may be any other material as long as it may reflect light.

Since the reflective layer 41 is disposed at a relatively lower position than the common emission layer 5 for emitting light, the light emitted from the common emission layer 5 may be reflected upward. Here, the upward indicates a direction in which the user can perceive light, for example, the side at which the encapsulation layer 8 or the color filter layer 9 is disposed. Therefore, it is possible to further increase the light efficiency of the first sub-pixel 21, the second sub-pixel 22, and the third sub-pixel 23 compared to a case in which there is no reflective layer 41, and the user can perceive high brightness, that is, clear image through the increased light efficiency.

The reflective layer 41 may be disposed inside the insulating layer 3. Specifically, the reflective layer 41 disposed in the first sub-pixel 21 may be disposed in the second insulating layer 3b, the reflective layer 41 disposed in the second sub-pixel 22 may be disposed in the fourth insulating layer 3d, and the reflective layer 41 disposed in the third sub-pixel 23 may be disposed in third insulating layer 3c, without being limited thereto. For example, as shown in FIG. 2, the reflective layer 41 disposed in the first sub-pixel 21 may be disposed so that an upper surface of the first insulating layer 3a or a lower surface of the second insulating layer 3b and a lower surface of the reflective layer 41 are positioned colinearly, the reflective layer 41 disposed in the second sub-pixel 22 may be disposed so that a lower surface of the fourth insulating layer 3d and the lower surface of the reflective layer 41 are positioned colinearly, and the reflective layer 41 disposed in the third sub-pixel 23 may be disposed so that a lower surface of the third insulating layer 3c and the lower surface of the reflective layer 41 are positioned colinearly. In the second sub-pixel 22, the upper surface of the reflective layer 41 may be positioned colinearly with an upper surface of the insulating layer 3 by an indentation IDP of the insulating layer 3, which will be described below.

The reflective layer 41 of each of the sub-pixels 21, 22, and 23 may be electrically connected to the transistors 31, 32, and 33 through the contact hole, and the connection electrode.

The reflective layer 41 positioned in the first sub-pixel 21 may be positioned closest to the substrate 2, then the reflective layer 41 positioned in the third sub-pixel 23 may be positioned close to the substrate 2, and finally, the reflective layer 41 positioned in the second sub-pixel 22 may be positioned furthest from the substrate 2. Conversely, the reflective layer 41 positioned in the first sub-pixel 21 may be positioned furthest from the second electrode 6, then the reflective layer 41 positioned in the third sub-pixel 23 may be positioned far from the second electrode 6, and finally, the reflective layer 41 positioned in the second sub-pixel 22 may be positioned closest to the second electrode 6.

As described above, it is because when the reflective layer 41 is formed to have various separation distances (or resonance distances) from the second electrode 6, it is possible to increase the light extraction efficiencies of different colors through reflection and re-reflection between the reflective layer 41 and the second electrode 6 according to the separation distance. Therefore, it is possible to increase the light extraction efficiency of red light in the first sub-pixel 21, increase the light extraction efficiency of blue light in the second sub-pixel 22, and increase the light extraction efficiency of green light in the third sub-pixel 23.

The transparent layer 42 is disposed on the reflective layer 41. The transparent layer 42 is used to supply holes to the common emission layer 5. The transparent layer 42 may be provided transparently so that the light reflected from the reflective layer 41 may travel upward. The transparent layer 42 may be made of a transparent material, but is not limited thereto and may be made of a thin metal material as long as it may transmit light. In addition, in the present specification, the first electrode 4 is described as having the double layer, but may have more layers. For example, the first electrode 4 may be formed by including a highly reflective metal material, such as a stacked structure (ITO/Al/ITO) of aluminum and ITO, an APC alloy, and a stacked structure (ITO/APC/ITO) of APC alloy and ITO. The APC alloy indicates an alloy of silver (Ag), palladium (Pb), and copper (Cu).

The transparent layer 42 may be electrically connected to the reflective layer 41 in direct contact with the reflective layer 41, or electrically connected to the reflective layer 41 by being indirectly connected to the reflective layer 41 through the contact hole and the connection electrode. As one example, in the second sub-pixel 22, the transparent layer 42 may be electrically connected to the reflective layer 41 by being direct contact with the reflective layer 41, and in each of the first sub-pixel 21 and the third sub-pixel 23, the transparent layer 42 may be electrically connected to the reflective layer 41 by being indirectly connected to the reflective layer 41, without being limited thereto. The reflective layer 41 may be connected to each of the first to third transistors 31, 32, and 33 through another contact hole to transmit the driving voltage provided by each of the first to third transistors 31, 32, and 33 to the transparent layer 42. The transparent layer 42 may supply holes to the common emission layer 5 when the driving voltage is applied from the first to third transistors 31, 32, and 33. In the second sub-pixel 22, the transparent layer 42 may be in direct contact with the reflective layer 41.

The transparent layer 42 may be disposed for each of the first to third sub-pixels 21, 22, and 23 to have substantially the same height at the upper surface of the reflective layer 41 or the insulating layer 3. In addition, the reflective layer 41 may be provided to have the same width as the transparent layer 42, but is not necessarily limited thereto and may be provided to have a larger width than the transparent layer 42 to further increase the amount of light reflected upward.

Meanwhile, the insulating layer 3 according to one embodiment may include at least one indentation IDP. For example, the indentation IDP may be formed by being indented in the thickness direction from the upper surface of the fourth insulating layer 3d. A thickness T2 of the fourth insulating layer 3d in which the indentation IDP is formed may be smaller than a thickness T1 of the fourth insulating layer 3d in which no indentation IDP is formed. The indentation IDP may be formed in the second sub-pixel 22. A width of the indentation IDP may be larger than a width of the second sub-pixel 22. In this case, the indentation IDP may also be formed in portions of the sub-pixels 21 and 23 adjacent to the second sub-pixel 22. However, the present specification is not limited thereto and the width of the indentation IDP may be the same as that of the second sub-pixel 22. The indentation IDP may be formed to have a larger width than the transparent layer 42. Since the transparent layer 42 is disposed in a space where the indentation IDP is formed in the second sub-pixel 22, the width of the indentation IDP is preferably larger than the width of the transparent layer 42. However, the present specification is not limited thereto, and the width of the indentation IDP may be the same as the width of the transparent layer 42.

Meanwhile, the indentation IDP is shown as being formed only in the entirety of the second sub-pixel 22 and the portions of the adjacent sub-pixels 21 and 23, but is not limited thereto, and may be formed in the entirety of the first sub-pixel 21 and portions of the adjacent sub-pixels 22 and 23 or formed in the entirety of the third sub-pixel 23 and portions of the adjacent sub-pixels 21 and 22. Hereinafter, for convenience of description, the description will focus on a case in which the indentation IDP is formed only in the entirety of the second sub-pixel 22 and the portions of the adjacent pixels 21 and 23.

In one embodiment, since the indentation IDP is formed on the entirety of the second sub-pixel 22, the transparent layer 42 of the second sub-pixel 22 disposed on the insulating layer 3 in which the indentation IDP is formed may be disposed under the transparent layers 42 of the adjacent sub-pixels 21 and 23 disposed on the insulating layer 3 in which no indentation IDP is formed. In other words, the transparent layer 42 of the second sub-pixel 22 disposed on the insulating layer 3 in which the indentation IDP is formed may be disposed closer to the substrate 2 than the transparent layer 42 of the adjacent sub-pixels 21 and 23 disposed on the insulating layer 3 in which no indentation IDP is formed is. Since the transparent layer 42 of each of the sub-pixels 21, 22, and 23 is made of the same material and formed in the same process, the thickness of the transparent layer 42 of each of the sub-pixels 21, 22, and 23 may all be the same. Therefore, a height of a surface of the transparent layer 42 of the second sub-pixel 22 may be positioned lower than heights of surfaces of the transparent layers 42 of the adjacent sub-pixels 21 and 23.

The bank BK may be disposed to cover an edge of the first electrode 4 or edges of the first electrode 4 and the reflective layer. The bank BK may be disposed at the boundaries of the adjacent sub-pixels 21, 22, and 23.

The bank BK is formed to surround and cover the edge of the transparent layer 42 on the insulating layer 3. Therefore, as shown in the cross-sectional view of FIG. 2, the bank BK may cover both ends of the transparent layer 42 provided in each of the first to third sub-pixels 21, 22, and 23. Specifically, the bank BK may be formed to cover a portion of upper surface and side surfaces at both ends of the transparent layer 42 and a portion of the upper surface of the insulating layer 3, and thus a current may be concentrated on the ends of the transparent layer 42, thereby solving the problem that luminous efficiency is reduced. The upper surface of the transparent layer 42 not covered and exposed by the bank BK becomes an emission area. The bank BK may be made of an organic insulating film or an inorganic insulating film comprising an organic insulating material such as acryl resin, epoxy resin, phenolic resin, polyamide resin, and/or polyimide resin, etc, or an inorganic insulating film comprising an inorganic insulating material such as silicon nitride, aluminum nitride, zirconium nitride, titanium nitride, hafnium nitride, tantalum nitride, silicon oxide, aluminum oxide, or titanium oxide, etc. Also, the bank BK may include a black dye in order to absorb light incident from the outside.

The bank BK between the adjacent sub-pixels 21 and 22 may fill a portion of the indentation IDP, may be in contact with upper and side surfaces of the fourth insulating layer 3d adjacent to the indentation IDP, and may be in direct contact with portions of the side and upper surfaces of each of the transparent layers 42 of the sub-pixels 21 and 22. The bank BK between the adjacent sub-pixels 22 and 23 may fill the portion of the indentation IDP, may be in contact with the upper and side surfaces of the fourth insulating layer 3d adjacent to the indentation IDP, and may be in direct contact with portions of the side and upper surfaces of each of the transparent layers 42 of the sub-pixels 22 and 23.

The bank BK according to one embodiment may have an asymmetric shape. In the present specification, when the bank BK has the asymmetric shape, it may mean that the bank BK has a left-right asymmetric shape with respect to boundary lines of the adjacent sub-pixels 21, 22, and 23. For example, the bank BK may include two side surfaces, and the bank BK with the asymmetric shape may have two side surfaces with different lengths. In the present specification, the length of the side surface may indicate a length in a direction in which the side surface extends. The reason why the bank BK has the asymmetric shape is that upper and lower positions of the transparent layers 42 of the adjacent sub-pixels 21, 22, and 23 are different. For example, the transparent layer 42 of the second sub-pixel 22 is disposed under the transparent layer 42 of the first sub-pixel 21, and the bank BK is disposed directly on the transparent layers 42 of the sub-pixels 21 and 22. Upon manufacturing the bank BK, after a bank insulating film including an organic insulating film is deposited across the sub-pixels 21, 22, and 23, the bank BK may be patterned to meet the boundaries of the sub-pixels 21, 22, and 23. An upper surface of the patterned bank BK may extend in the horizontal direction, and each of side surfaces thereof may extend to the transparent layers 42 adjacent to the upper surface, and as described above, since the upper and lower positions of the transparent layers 42 of the adjacent sub-pixels 21, 22, and 23 are different, lengths between the side surfaces of the bank BK may be formed differently.

As shown in FIG. 2, for example, the bank BK at the boundary of the adjacent sub-pixels 21 and 22 may have a length of a side surface at the second sub-pixel 22 side which is larger than a side surface at the first sub-pixel 21 side, and the bank BK at the boundary of the adjacent sub-pixels 22 and 23 may have the length of the side surface at the second sub-pixel 22 side which is larger than a length of a side surface at the third sub-pixel 23 side.

The common emission layer 5 is formed on the first electrode 4 and the insulating layer 3. The common emission layer 5 may be formed on the bank BK disposed between the plurality of sub-pixels 21, 22, and 23. Therefore, the common emission layer 5 may be in contact with the upper surface of the transparent layer 42 of the first electrode 4. The common emission layer 5 may be in contact with the upper surface of the transparent layer 42 exposed by the bank BK, the side surfaces of the adjacent banks BK, and the upper surfaces of the banks BK.

The OLED according to one embodiment may include the first electrode 4 or ANO, the second electrode 6 or CAT, and the common emission layer 5 between the first electrode 4 and the second electrode 6.

The common emission layer 5 may be provided to emit white (W) light. To this end, the common emission layer 5 may include a plurality of stacks for emitting light of different colors. Specifically, the common emission layer 5 may include a first stack, a second stack, and a charge generation layer CGL provided between the first stack and the second stack.

The second electrode 6 is formed on the common emission layer 5. The second electrode 6 may function as the cathode of the display device 2. Like the common emission layer 5, the second electrode 6 is formed in each of the sub-pixels 21, 22, and 23 and therebetween.

In the display device 1 according to one embodiment, the second electrode 6 may be formed as a translucent electrode to implement white light with luminous efficiency in the top emission type. Therefore, the micro cavity effect can be obtained for each of the first to third sub-pixels 21, 22, and 23. When the second electrode 6 is formed as the translucent electrode, reflection and re-reflection of light may be repeated between the second electrode 6 and the reflective layer 41 to obtain the micro cavity effect, thereby increasing light extraction efficiency.

Meanwhile, since the second electrode 6 is formed on the upper surface of the common emission layer 5, the second electrode 6 may be formed along a profile of the common emission layer 5. Since the common emission layer 5 is formed along a profile of the transparent layer 42 of the first electrode 4 in the emission area, as a result, the second electrode 6 may be formed along the profile of the transparent layer 42 of the first electrode 4. In addition, the capping layer 7 on the second electrode 6 may also be formed along a profile of the second electrode 6.

The capping layer 7 may be made of an inorganic insulating material, but is not limited thereto. The capping layer 7 may be disposed on the second electrode 6 to protect the OLED.

The encapsulation layer 8 is formed on the second electrode 6 and functions to prevent external moisture from entering the common emission layer 5. The encapsulation layer 8 may be made of an inorganic insulating material or may be formed in a structure in which an inorganic insulating material and an organic insulating material are alternately stacked, but is not necessarily limited thereto.

The color filter layer 9 is formed on the encapsulation layer 8. The color filter layer 9 may include the red (R) first color filter 91 provided in the second sub-pixel 22, the blue (B) second color filter 92 provided in the second sub-pixel 22, and the green (G) third color filter 93 provided in the third sub-pixel 23, but is not necessarily limited thereto.

As shown in FIG. 3, the common emission layer 5 may include a first stack EL1, a second stack EL2, and a first charge generation layer CGL1, which are provided on the first electrode 4.

The first stack EL1 may be provided on the first electrode 4 and configured in a structure in which a hole injecting layer HIL, a hole transporting layer HTL, a blue (B) emitting layer EML1, and an electron transporting layer (ETL) may be stacked sequentially.

The first stack EL1 may be disposed between the first sub-pixel 21 and the second sub-pixel 22 and disposed between the second sub-pixel 22 and the third sub-pixel 23, that is, on the bank BK.

The first charge generation layer CGL1 functions to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The first charge generation layer CGL1 may be disposed between the first sub-pixel 21 and the second sub-pixel 22 and disposed between the second sub-pixel 22 and the third sub-pixel 23, that is, on the bank BK. Meanwhile, in the display device 1 according to one embodiment, since the common emission layer 5 is also disposed between the sub-pixels 21, 22, and 23, when any one sub-pixel emits light, a lateral leakage current may occur to the adjacent sub-pixels 21, 22, and 23 through the first charge generation layer CGL1, but since the bank BK with a predetermined height is disposed between the sub-pixels 21, 22, and 23, a current path may increase, thereby preventing the occurrence of the lateral leakage current. Furthermore, since the bank BK has the asymmetric shape, a thickness of the first charge generation layer CGL1 may decrease at one or more side surfaces of the bank BK. Therefore, the first charge generation layer CGL1 may be physically separated from the at least one side surface of the bank BK. Detailed description thereof will be made below.

The second stack EL2 may be provided on the first stack EL1 and configured in a structure in which the hole transporting layer HTL, a yellow green (YG) emitting layer EML2, the electron transporting layer ETL, and the electron injecting layer EIL are stacked sequentially.

The second stack EL2 may be disposed between the first sub-pixel 21 and the second sub-pixel 22 and disposed between the second sub-pixel 22 and the third sub-pixel 23, that is, on the bank BK.

As a result, the common emission layer 5 may be provided as a common layer throughout the first to third sub-pixels 21, 22, and 23 as shown in FIG. 2.

As shown in FIG. 4, a common emission layer 5_1 of the OLED according to one embodiment may include the first stack EL1 provided on the first electrode 4, the second stack EL2, the third stack EL3, the first charge generation layer CGL1 between the first stack EL1 and the second stack EL2, and the second charge generation layer CGL2 between the second stack EL2 and the third stack EL3.

The first stack EL1 may be provided on the first electrode 4 and configured in a structure in which the hole injecting layer HIL, the hole transporting layer HTL, a blue (B) emitting layer EML1, and the electron transporting layer ETL are stacked sequentially.

The first stack EL1 may be disposed between the first sub-pixel 21 and the second sub-pixel 22 and disposed between the second sub-pixel 22 and the third sub-pixel 23, that is, on the bank BK.

The first charge generation layer CGL1 functions to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may include a metal material as a dopant.

The first charge generation layer CGL1 may be disposed between the first sub-pixel 21 and the second sub-pixel 22 and disposed between the second sub-pixel 22 and the third sub-pixel 23, that is, on the bank BK. Meanwhile, in the display device 1 according to one embodiment, since the common emission layer 5 is also disposed between the sub-pixels 21, 22, and 23, when any one sub-pixel emits light, a lateral leakage current may occur to the adjacent sub-pixels 21, 22, and 23 through the first charge generation layer CGL1, but since the bank BK with a predetermined height is disposed between the sub-pixels 21, 22, and 23, a current path may increase, thereby preventing the occurrence of the lateral leakage current. Furthermore, since the bank BK has the asymmetric shape, a thickness of the first charge generation layer CGL1 may decrease at one or more side surfaces of the bank BK. Therefore, the first charge generation layer CGL1 may be physically separated from the at least one side surface of the bank BK. Detailed description thereof will be made below.

The second stack EL2 may be provided on the first stack EL1 and configured in a structure in which the hole transporting layer HTL, a green (G) emitting layer EML2, the electron transporting layer ETL are stacked sequentially.

The second stack EL2 may be disposed between the first sub-pixel 21 and the second sub-pixel 22 and disposed between the second sub-pixel 22 and the third sub-pixel 23, that is, on the bank BK.

The second charge generation layer CGL2 functions to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may include a metal material as a dopant.

The second charge generation layer CGL2 may be disposed between the first sub-pixel 21 and the second sub-pixel 22 and disposed between the second sub-pixel 22 and the third sub-pixel 23, that is, on the bank BK. Meanwhile, in the display device 1 according to one embodiment, since the common emission layer 5 is also disposed between the sub-pixels 21, 22, and 23, when any one sub-pixel emits light, the lateral leakage current may occur to the adjacent sub-pixels 21, 22, and 23 through the second charge generation layer CGL2, but since the bank BK with the predetermined height is disposed between the sub-pixels 21, 22, and 23, a current path may increase, thereby preventing the occurrence of the lateral leakage current. Furthermore, since the bank BK has the asymmetric shape, a thickness of the second charge generation layer CGL2 may decrease at one or more side surfaces of the bank BK. Therefore, the second charge generation layer CGL2 may be physically separated from the at least one side surface of the bank BK. Detailed description thereof will be made below.

The third stack EL3 may be provided on the second stack EL2 and configured in a structure in which the hole transporting layer HTL, a red (R) emitting layer EML3, the electron transporting layer ETL, and the electron injecting layer EIL are stacked sequentially.

Referring back to FIG. 2, the second electrode 6 is formed on the common emission layer 5, the encapsulation layer 8 is formed on the second electrode 6, and the color filter layer 9 is formed on the encapsulation layer 8.

Although not shown, black matrices for preventing color mixing between the sub-pixels may be provided between the first to third color filters 91, 92, and 93.

Hereinafter, the bank BK with the asymmetric shape according to one embodiment will be described in detail.

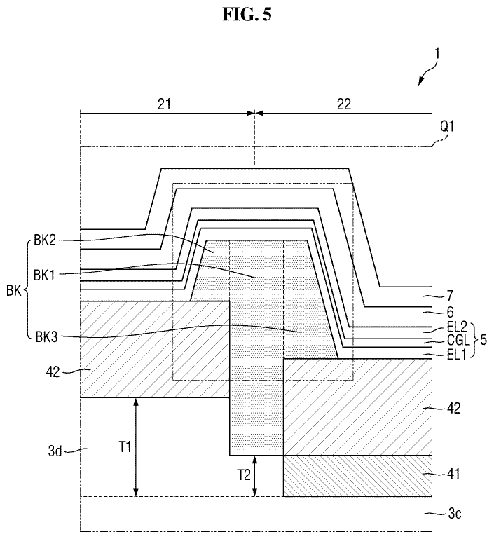

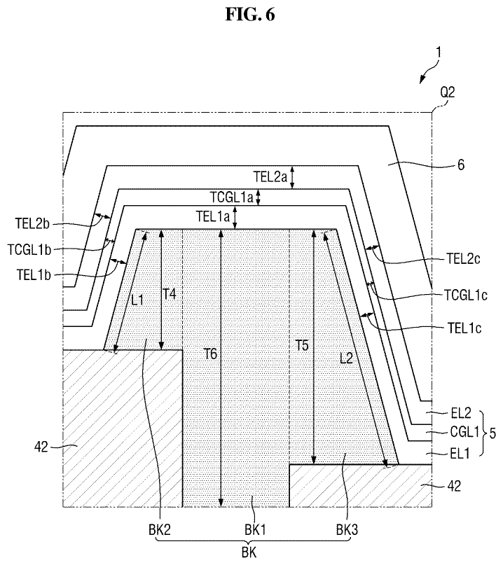

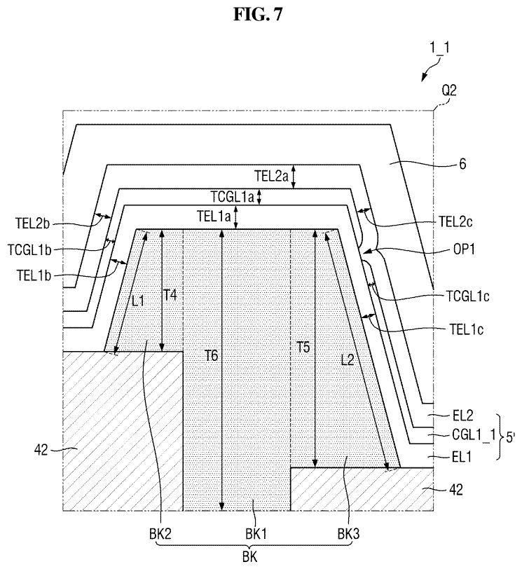

FIG. 5 is an enlarged view of area Q1 in FIG. 2 according to one embodiment. FIG. 6 is an enlarged view of area Q2 in FIG. 5 according to one embodiment. FIG. 7 is an enlarged view of area Q2 of the display device of FIG. 5 according to the modified example.

Referring to FIGS. 5 to 7, the bank BK has the asymmetric shape, and the bank BK may include a first part BK1, a second part BK2, and a third part BK3.

As shown in FIG. 5, a portion (or a lower end portion) of the first part BK1 may be disposed in the indentation IDP, and the other portion (or an upper portion) of the first part BK1 may protrude upward from the indentation IDP. Side surfaces of the first part BK1 may be in contact with the transparent layers 42 of the adjacent sub-pixels 21 and 22, respectively. Upper and lower surfaces of the first part BK1 may be flat. The second part BK2 may be disposed in the first sub-pixel 21. The second part BK2 may be in direct contact with the first part BK1. An inner surface of the second part BK2 may be in direct contact with the first part BK1, and an outer surface of the second part BK2 may be inclined. In the present specification, the term “inclined” may indicate extending in a direction between an extension direction (or a horizontal direction) of the substrate 2 (see FIG. 2) and a vertical direction (vertical direction or thickness direction) of the substrate 2. The third part BK3 may be disposed in the second sub-pixel 22. The third part BK3 may be in direct contact with the first part BK1. An inner surface of the third part BK3 may be in direct contact with the first part BK1, and an outer surface of the third part BK3 may be inclined. The second part BK2 and the third part BK3 may be asymmetrical with respect to the first part BK1. For example, a thickness of the third part BK3 may be larger than a thickness of the second part BK2, and a length of the outer surface of the third part BK3 may be larger than a length of the outer surface of the second part BK2. The outer surface of the third part BK3 and the outer surface of the second part BK2 may each be one of the side surfaces of the bank BK. Upper surfaces of the second part BK2 and the third part BK3 may each be flat.

A lower surface of the second part BK2 may be in direct contact with an upper surface of the transparent layer 42 of the first sub-pixel 21. A lower surface of the third part BK3 may be in direct contact with an upper surface of the transparent layer 42 of the second sub-pixel 22.

As shown in FIG. 6, a thickness T6 of the first part BK1 may be larger than a thickness T4 of the second part BK2 and a thickness T5 of the third part BK3. The thickness T5 of the third part BK3 may be larger than the thickness T4 of the second part BK2. A length L2 of the outer surface of the third part BK3 may be larger than a length L1 of the outer surface of the second part BK2. As described above, the reason why the second part BK2 and the third part BK3 have different shapes with respect to the first part BK1 is that as described above, the upper and lower positions of the transparent layers 42 of the adjacent sub-pixels 21, 22, and 23 are different. For example, the transparent layer 42 of the second sub-pixel 22 is disposed under the transparent layer 42 of the first sub-pixel 21, and the bank BK is disposed directly on the transparent layers 42 of the sub-pixels 21 and 22. For example, the transparent layer 42 of the second sub-pixel 22 is disposed lower than the transparent layer 42 of the third sub-pixel 23, and the bank BK is disposed directly on the transparent layers 42 of the sub-pixels 22 and 23. Upon manufacturing the bank BK, after a bank insulating film including an organic insulating film is deposited across the sub-pixels 21, 22, and 23, the bank BK may be patterned to meet the boundaries of the sub-pixels 21, 22, and 23. An upper surface of the patterned bank BK may extend in the horizontal direction, and side surfaces thereof may respectively extend to the transparent layers 42 adjacent to the upper surface, and as described above, since the upper and lower positions of the transparent layers 42 of the adjacent sub-pixels 21, 22, and 23 are different, the thickness T5 of the third part BK3 may be larger than the thickness T4 of the second part BK2, and the length L2 of the outer surface of the third part BK3 may be larger than the length L1 of the outer surface of the second part BK2.

Meanwhile, the plurality of layers EL1, CGL1, and EL2 of the common emission layer 5 of the OLED described above in FIG. 4 may have different thicknesses according to the areas disposed on the bank BK.

For example, thicknesses TEL1a, TCGL1a, and TEL2a of the plurality of layers EL1, CGL1, and EL2 on the upper surface of the bank BK may be larger than thicknesses TEL1b, TCGL1b, and TEL2b of the plurality of layers EL1, CGL1, and EL2 on a first side surface of the bank BK of the first sub-pixel 21 and thicknesses TEL1c, TCGL1c, and TEL2c of the plurality of layers EL1, CGL1, and EL2 on a second side surface of the bank BK of the second sub-pixel 22, respectively, and the thicknesses TEL1b, TCGL1b, and TEL2b of the plurality of layers EL1, CGL1, and EL2 on the first side surface of the bank BK of the first sub-pixel 21 may be larger than the thicknesses TEL1c, TCGL1c, and TEL2c of the plurality of layers EL1, CGL1, and EL2 on the second side surface of the bank BK of the second sub-pixel 22, respectively. The reason why the thicknesses TEL1a, TCGL1a, and TEL2a of the plurality of layers EL1, CGL1, and EL2 on the upper surface of the bank BK may be larger than the thicknesses TEL1b, TCGL1b, and TEL2b of the plurality of layers EL1, CGL1, and EL2 on the first side surface of the bank BK of the first sub-pixel 21 and the thicknesses TEL1c, TCGL1c, and TEL2c of the plurality of layers EL1, CGL1, and EL2 on the second side surface of the bank BK of the second sub-pixel 22, respectively, and the thicknesses TEL1b, TCGL1b, and TEL2b of the plurality of layers EL1, CGL1, and EL2 on the first side surface of the bank BK of the first sub-pixel 21 may be larger than the thicknesses TEL1c, TCGL1c, and TEL2c of the plurality of layers EL1, CGL1, and EL2 on the second side surface of the bank BK of the second sub-pixel 22, respectively is that when a common emission material layer including an organic material is applied, the common emission material layer may flow down to reduce the thickness on the side surface of the bank BK. Therefore, the thicknesses TEL1a, TCGL1a, and TEL2a of the plurality of layers EL1, CGL1, and EL2 on the upper surface of the bank BK may be larger than the thicknesses TEL1b, TCGL1b, and TEL2b of the plurality of layers EL1, CGL1, and EL2 on the first side surface of the bank BK of the first sub-pixel 21 and the thicknesses TEL1c, TCGL1c, and TEL2c of the plurality of layers EL1, CGL1, and EL2 on the second side surface of the bank BK of the second sub-pixel 22, respectively.

Therefore, since the length L2 of the second side surface of the bank BK is larger than the length L1 of the first side surface thereof, the thicknesses TEL1b, TCGL1b, and TEL2b of the plurality of layers EL1, CGL1, and EL2 on the first side surface of the bank BK of the first sub-pixel 22 may be larger than the thicknesses TEL1c, TCGL1c, and TEL2c of the plurality of layers EL1, CGL1, and EL2 on the second side surface of the bank BK of the second sub-pixel 22.

Furthermore, the thicknesses TCGL1a, TCGL1b, and TCGL1c of the first charge generation layer CGL1 may be smaller than the thicknesses of other layers of the common emission layer 5. In other words, the first charge generation layer CGL1 may have a smaller thickness than each of the layers HIL, HTL, EML1, ETL, EML2, and EIL forming the first stack EL1 and the second stack EL2.

In the specification, when the thicknesses between the layers or stacks of the common emission layer 5 positioned on the bank BK and the first charge generation layer CGL1 are small and large, it may mean an average thickness.

Therefore, the first charge generation layer CGL1 may have a very high possibility of being physically separated compared to other layers of the common emission layer 5 on the side surfaces of the bank BK.

In addition, as described above, since the length L2 of the second side surface of the bank BK is larger than the length L1 of the first side surface thereof, the thickness TEL1c of the first charge generation layer CGL1 on the second side surface of the bank BK of the second sub-pixel 22 is smaller than the thickness TEL1b of the first charge generation layer CGL1 on the first side surface of the bank BK of the first sub-pixel 21, and thus the first charge generation layer CGL1 on the second side surface of the bank BK may be more likely to be separated. In conclusion, in one embodiment, since the bank BK has an asymmetric shape to induce the physical separation of the first charge generation layer CGL1 from at least one of the side surfaces of the bank BK, the first charge generation layer CGL1 may not be formed integrally with the sub-pixels 21, 22, and 23 but may be physically separated from at least one of the side surfaces of the bank BK. Therefore, it is possible to prevent the occurrence of the lateral leakage current between the adjacent sub-pixels 21, 22, and 23. As a result, it is possible to block the occurrence of color mixing between the adjacent sub-pixels 21, 22, and 23 in advance.

FIG. 7 is an enlarged view of area Q2 of the display device of FIG. 5 according to the modified example.

Referring to FIGS. 1 to 7, a first charge generation layer CGL1_1 of a common emission layer 5′ of the display device 1 according to the present embodiment may be physically separated from the outer surface of the third part BK3 (or the second side surface of the bank BK) by the mechanism described above in FIG. 6. A first opening OP1 may be formed between the physically separated first charge generation layers CGL1_1. The second stack EL2 positioned on the first charge generation layer CGL1_1 may be in direct contact with the first stack EL1 through the first opening OP1.

Since the remaining descriptions have been made above with reference to FIGS. 1 to 6, detailed description thereof will be omitted below.

Hereinafter, a method of manufacturing a display device according to one embodiment or a modified example will be described. In describing the method of manufacturing the display device below, overlapping descriptions of the parts described in FIGS. 1 to 7 will be omitted.

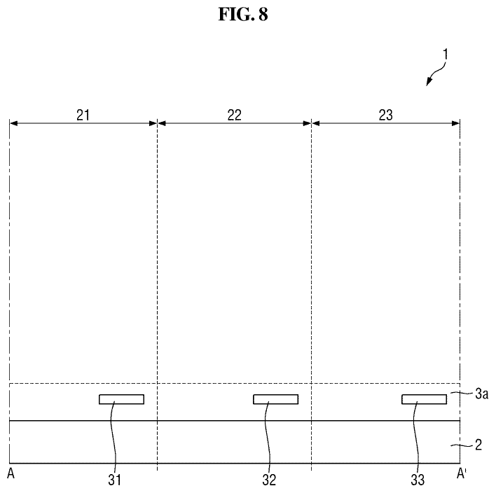

FIGS. 8 to 18 are cross-sectional views for each process in a method of manufacturing the display device according to one embodiment. In describing the method of manufacturing the display device with reference to FIGS. 8 to 18, FIGS. 1 to 7 may also be referred.

Referring to FIGS. 2 and 8, a first insulating layer 3a is formed on the substrate 2. The transistors 31, 32, and 33 may be positioned in the first insulating layer 3a. The first insulating layer 3a may protect the transistors 31, 32, and 33. The first insulating layer 3a may be made of an organic insulating material, but is not necessarily limited thereto and may be made of an inorganic insulating material.

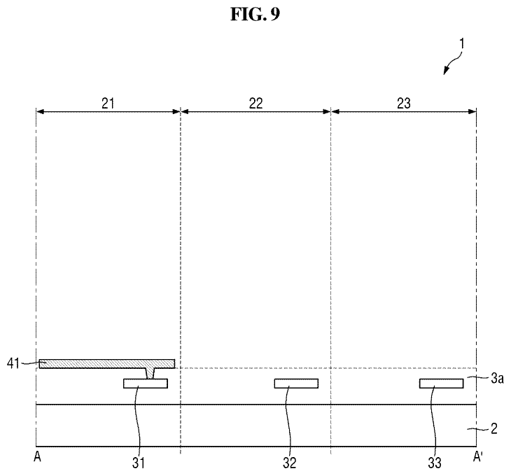

Subsequently, referring to FIGS. 2 and 9, the reflective layer 41 is formed on the first insulating layer 3a of the first sub-pixel 21. The reflective layer 41 is connected to the source terminal or the drain terminal of the driving thin film transistor of the first transistor 31 through the contact hole.

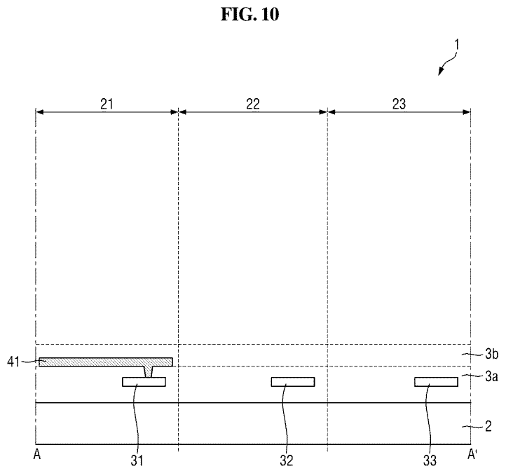

Subsequently, referring to FIGS. 2 and 10, a second insulating layer 3b is formed on the first insulating layer 3a and the reflective layer 41 of the first sub-pixel 21. The second insulating layer 3b may be made of an organic insulating material, but is not necessarily limited thereto and may be made of an inorganic insulating material. The second insulating layer 3b may cover and protect the reflective layer 41 of the first sub-pixel 21.

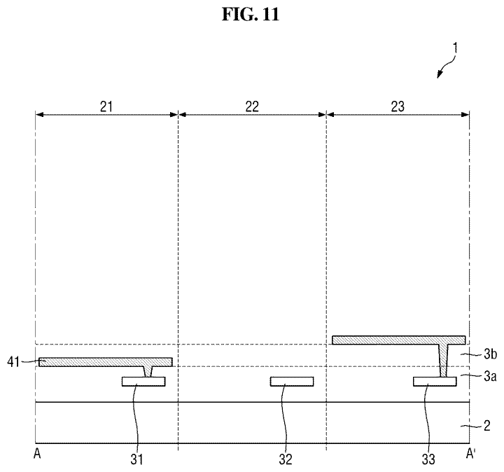

Subsequently, referring to FIGS. 2 and 11, the reflective layer 41 is formed on the second insulating layer 3b of the third sub-pixel 23. The reflective layer 41 is connected to the source terminal or the drain terminal of the driving thin film transistor of the third transistor 33 through the contact hole.

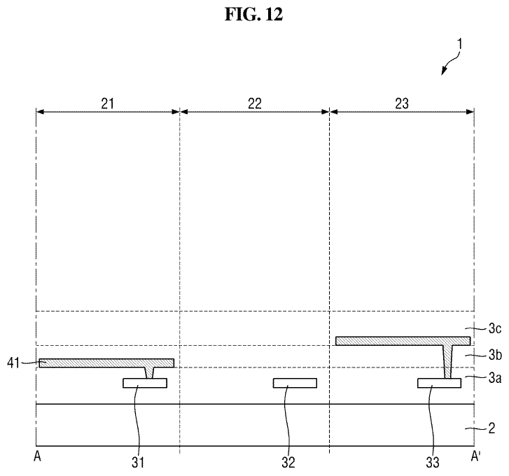

Subsequently, referring to FIGS. 2 and 12, a third insulating layer 3c is formed on the second insulating layer 3b and the reflective layer 41 of the third sub-pixel 23. The third insulating layer 3c may be made of an organic insulating material, but is not necessarily limited thereto and may be made of an inorganic insulating material. The third insulating layer 3c may cover and protect the reflective layer 41 of the third sub-pixel 23.

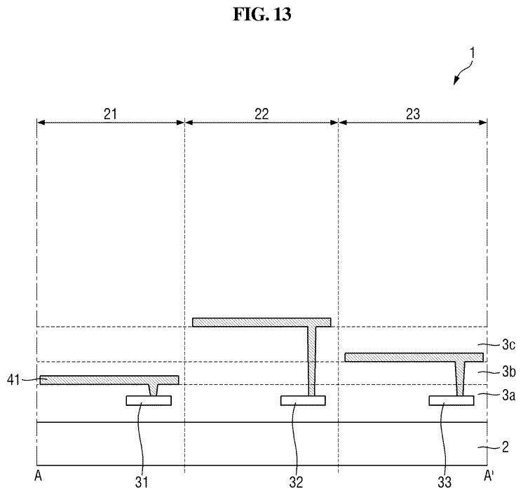

Subsequently, referring to FIGS. 2 and 13, the reflective layer 41 is formed on the third insulating layer 3c of the second sub-pixel 22. The reflective layer 41 is connected to the source terminal or the drain terminal of the driving thin film transistor of the second transistor 32 through the contact hole.

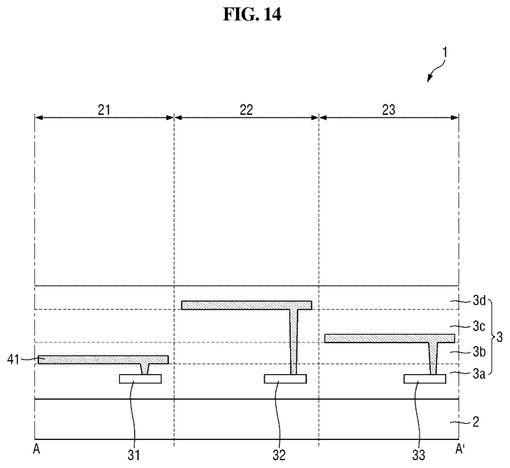

Subsequently, referring to FIGS. 2 and 14, a fourth insulating layer 3d′ is formed on the third insulating layer 3c and the reflective layer 41 of the second sub-pixel 22. The fourth insulating layer 3d′ may be made of an organic insulating material, but is not necessarily limited thereto and may be made of an inorganic insulating material. The fourth insulating layer 3d′ may cover and protect the reflective layer 41 of the second sub-pixel 22.

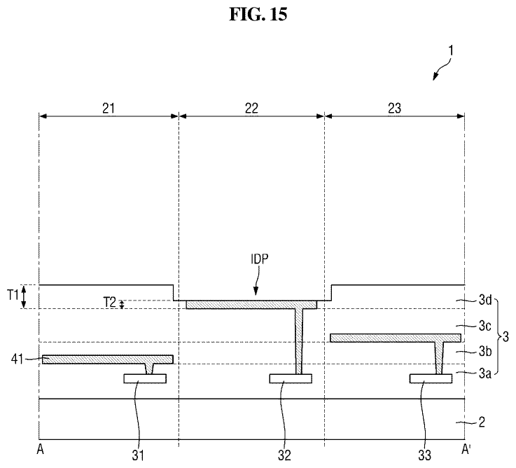

Subsequently, referring to FIGS. 2 and 15, the indentation IDP is formed in the fourth insulating layer 3d. For example, the indentation IDP may be formed by being indented in the thickness direction from the upper surface of the fourth insulating layer 3d. The thickness T2 of the fourth insulating layer 3d in which the indentation IDP is formed may be smaller than the thickness T1 of the fourth insulating layer 3d in which no indentation IDP is formed. The indentation IDP may be formed in the second sub-pixel 22. The width of the indentation IDP may be larger than the width of the second sub-pixel 22. In this case, the indentation IDP may also be formed in portions of the sub-pixels 21 and 23 adjacent to the second sub-pixel 22. However, the present specification is not limited thereto and the width of the indentation IDP may be the same as that of the second sub-pixel 22. The indentation IDP may be formed to have a larger width than the transparent layer 42. Since the transparent layer 42 is disposed in a space where the indentation IDP is formed in the second sub-pixel 22, the width of the indentation IDP is preferably larger than the width of the transparent layer 42. However, the present specification is not limited thereto, and the width of the indentation IDP may be the same as the width of the transparent layer 42.

Meanwhile, the indentation IDP is shown as being formed only in the entirety of the second sub-pixel 22 and the portions of the adjacent sub-pixels 21 and 23, but is not limited thereto, and may be formed in the entirety of the first sub-pixel 21 and portions of the adjacent sub-pixels 22 and 23 or formed in the entirety of the third sub-pixel 23 and portions of the adjacent sub-pixels 21 and 22. Hereinafter, for convenience of description, the description will focus on a case in which the indentation IDP is formed only in the entirety of the second sub-pixel 22 and the portions of the adjacent pixels 21 and 23.

The fourth insulating layer 3d in which the indentation IDP is formed may be positioned colinearly with the upper surface of the reflective layer 41 of the second sub-pixel 22.

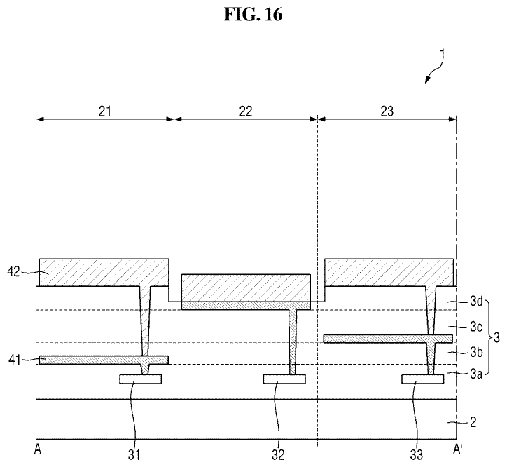

Subsequently, referring to FIGS. 2 and 16, the transparent layer 42 is formed on the fourth insulating layer 3d of each of the sub-pixel 21, 22, and 23.

In one embodiment, since the indentation IDP is formed on the entirety of the second sub-pixel 22, the transparent layer of the second sub-pixel 22 disposed on the insulating layer 3 in which the indentation IDP is formed may be disposed under the transparent layers 42 of the adjacent sub-pixels 21 and 23 disposed on the insulating layer 3 in which no indentation IDP is formed. In other words, the transparent layer 42 of the second sub-pixel 22 disposed on the insulating layer 3 in which the indentation IDP is formed may be disposed closer to the substrate 2 than the transparent layer 42 of the adjacent sub-pixels 21 and 23 disposed on the insulating layer 3 in which no indentation IDP is formed is. Since the transparent layer 42 of each of the sub-pixels 21, 22, and 23 is made of the same material and formed in the same process, the thickness of the transparent layer 42 of each of the sub-pixels 21, 22, and 23 may all be the same. Therefore, the height of the surface of the transparent layer 42 of the second sub-pixel 22 may be positioned lower than the heights of surfaces of the transparent layers 42 of the adjacent sub-pixels 21 and 23.

The transparent layer 42 is disposed on the reflective layer 41. The transparent layer 42 is used to supply holes to the common emission layer 5. The transparent layer 42 may be provided transparently so that the light reflected from the reflective layer 41 may travel upward. The transparent layer 42 may be made of a transparent material, but is not limited thereto and may be made of a thin metal material as long as it may transmit light. In addition, in the present specification, the first electrode 4 is described as having the double layer, but may have more layers. For example, the first electrode 4 may be formed by including a highly reflective metal material, such as a stacked structure (ITO/Al/ITO) of aluminum and ITO, an APC alloy, and a stacked structure (ITO/APC/ITO) of APC alloy and ITO. The APC alloy indicates an alloy of silver (Ag), palladium (Pb), and copper (Cu).

The transparent layer 42 may be electrically connected to the reflective layer 41 in direct contact with the reflective layer 41, or electrically connected to the reflective layer 41 by being indirectly connected to the reflective layer 41 through the contact hole and the connection electrode. The reflective layer 41 may be connected to each of the first to third transistors 31, 32, and 33 through another contact hole to transmit the driving voltage provided by each of the first to third transistors 31, 32, and 33 to the transparent layer 42. The transparent layer 42 may supply holes to the common emission layer 5 when the driving voltage is applied from the first to third transistors 31, 32, and 33. In the second sub-pixel 22, the transparent layer 42 may be in direct contact with the reflective layer 41.

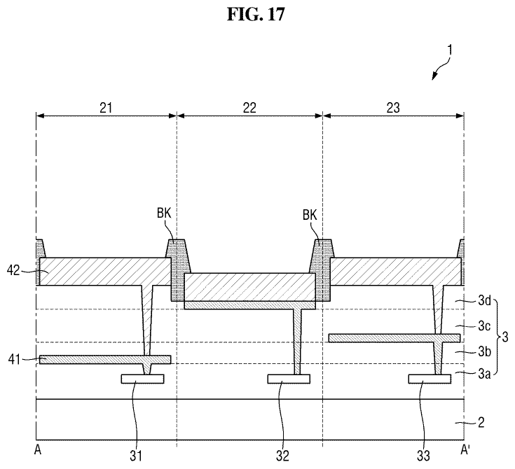

Subsequently, referring to FIGS. 2 and 17, the bank BK is formed to surround and cover the edge of the transparent layer 42 on the insulating layer 3. Therefore, the bank BK may cover both ends of the transparent layer 42 provided in each of the first to third sub-pixels 21, 22, and 23. Specifically, the bank BK may be formed to cover a portion of upper surface and side surfaces at both ends of the transparent layer 42 and a portion of the upper surface of the insulating layer 3, and thus a current may be concentrated on the ends of the transparent layer 42, thereby solving the problem that luminous efficiency is reduced. The upper surface of the transparent layer 42 not covered and exposed by the bank BK becomes an emission area. The bank BK may be made of an organic insulating film or an inorganic insulating film.

The bank BK between the adjacent sub-pixels 21 and 22 may fill the portion of the indentation IDP, may be in contact with the upper and side surfaces of the fourth insulating layer 3d adjacent to the indentation IDP, and may be in direct contact with portions of the side and upper surfaces of each of the transparent layers 42 of the sub-pixels 21 and 22. The bank BK between the adjacent sub-pixels 22 and 23 may fill the portion of the indentation IDP, may be in contact with the upper and side surfaces of the fourth insulating layer 3d adjacent to the indentation IDP, and may be in direct contact with portions of the side and upper surfaces of each of the transparent layers 42 of the sub-pixels 22 and 23.

The bank BK according to one embodiment may have an asymmetric shape. The reason why the bank BK has the asymmetric shape is that upper and lower positions of the transparent layers 42 of the adjacent sub-pixels 21, 22, and 23 are different. Since the above description has been made in detail in FIGS. 2, 5, and 6, detailed descriptions thereof will be omitted.

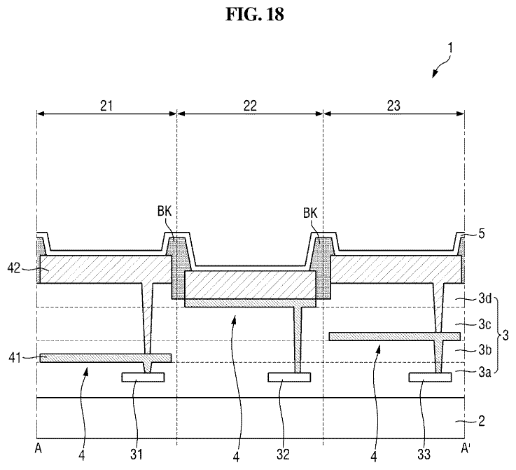

Subsequently, referring to FIGS. 2 and 18, the common emission layer 5 is formed on the first electrode 4 and the insulating layer 3. The common emission layer 5 may be formed on the bank BK disposed between the plurality of sub-pixels 21, 22, and 23. Therefore, the common emission layer 5 may be in contact with the upper surface of the transparent layer 42 of the first electrode 4. The common emission layer 5 may be in contact with the upper surface of the transparent layer 42 exposed by the bank BK, the side surfaces of the adjacent banks BK, and the upper surfaces of the banks BK. As described above in FIG. 3, the common emission layer 5 may include the first stack EL1 provided on the first electrode 4, the second stack EL2, and the first charge generation layer CGL1, or as described above in FIG. 4, the common emission layer 5_1 may include the first stack EL1 provided on the first electrode 4, the second stack EL2, the third stack EL3, the first charge generation layer CGL1 between the first stack EL1 and the second stack EL2, and the second charge generation layer CGL2 between the second stack EL2 and the third stack EL3.

As described above in FIG. 6, the thickness T6 of the first part BK1 may be larger than the thickness T4 of the second part BK2 and the thickness T5 of the third part BK3, and the thickness T5 of the third part BK3 may be larger than the thickness T4 of the second part BK2. The length L2 of the outer surface of the third part BK3 may be larger than the length L1 of the outer surface of the second part BK2. Therefore, the plurality of layers EL1, CGL1, and EL2 of the common emission layer 5 of the OLED may have different thicknesses according to the areas disposed on the bank BK.

For example, the thicknesses TEL1a, TCGL1a, and TEL2a of the plurality of layers EL1, CGL1, and EL2 on the upper surface of the bank BK may be larger than the thicknesses TEL1b, TCGL1b, and TEL2b of the plurality of layers EL1, CGL1, and EL2 on the first side surface of the bank BK of the first sub-pixel 21 and the thicknesses TEL1c, TCGL1c, and TEL2c of the plurality of layers EL1, CGL1, and EL2 on the second side surface of the bank BK of the second sub-pixel 22, respectively, and the thicknesses TEL1b, TCGL1b, and TEL2b of the plurality of layers EL1, CGL1, and EL2 on the first side surface of the bank BK of the first sub-pixel 21 may be larger than the thicknesses TEL1c, TCGL1c, and TEL2c of the plurality of layers EL1, CGL1, and EL2 on the second side surface of the bank BK of the second sub-pixel 22, respectively.

Furthermore, the thicknesses TCGL1a, TCGL1b, and TCGL1c of the first charge generation layer CGL1 may be smaller than the thicknesses of other layers of the common emission layer 5. In other words, the first charge generation layer CGL1 may have a smaller thickness than each of the layers HIL, HTL, EML1, ETL, EML2, and EIL forming the first stack EL1 and the second stack EL2.

Therefore, the first charge generation layer CGL1 may have a very high possibility of being physically separated compared to other layers of the common emission layer 5 on the side surfaces of the bank BK.

In addition, as described above, since the length L2 of the second side surface of the bank BK is larger than the length L1 of the first side surface thereof, the thickness TEL1c of the first charge generation layer CGL1 on the second side surface of the bank BK of the second sub-pixel 22 is smaller than the thickness TEL1b of the first charge generation layer CGL1 on the first side surface of the bank BK of the first sub-pixel 21, and thus the first charge generation layer CGL1 on the second side surface of the bank BK may be more likely to be separated. In conclusion, in one embodiment, since the bank BK has an asymmetric shape to induce the physical separation of the first charge generation layer CGL1 from at least one of the side surfaces of the bank BK, the first charge generation layer CGL1 may not be formed integrally with the sub-pixels 21, 22, and 23 but may be physically separated from at least one of the side surfaces of the bank BK. Therefore, it is possible to prevent the occurrence of the lateral leakage current between the adjacent sub-pixels 21, 22, and 23. As a result, it is possible to block the occurrence of color mixing between the adjacent sub-pixels 21, 22, and 23 in advance.

Hereinafter, a display device according to another embodiment will be described.

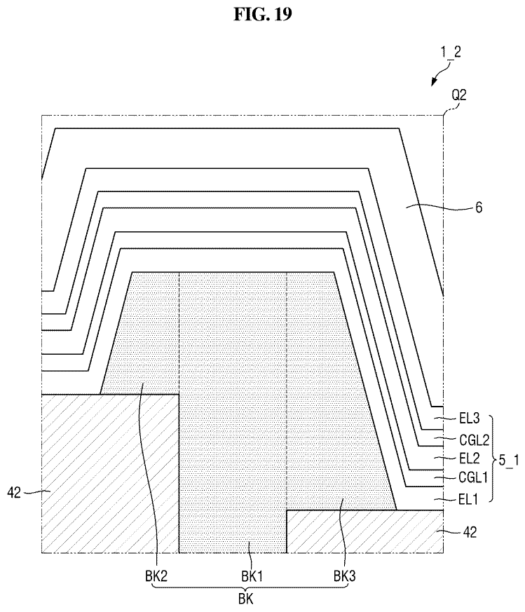

FIG. 19 is an enlarged view of area Q2 of the display device of FIG. 5 according to another embodiment.

Referring to FIG. 19, a display device 1_2 according to the present embodiment differs from the display device 1 shown FIG. 2 in that the common emission layer 5_1 shown FIG. 4 can be applied. Since the common emission layer 5_1 has been described above in FIG. 4, detailed description thereof will be omitted below.

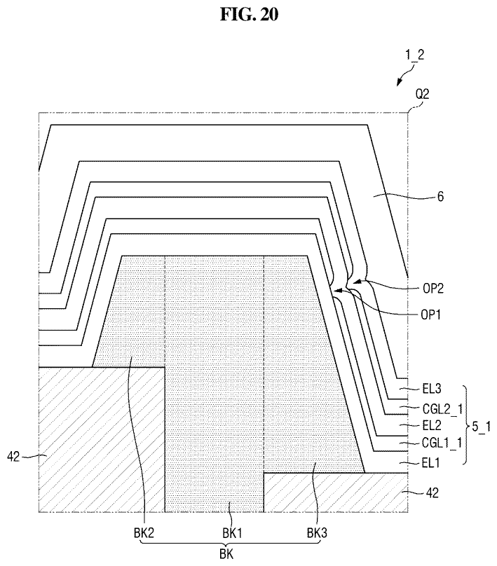

FIG. 20 is an enlarged view of area Q2 of the display device of FIG. 5 according to still another embodiment.

Referring to FIG. 20, a display device 1_2 according to the present embodiment differs from the display device shown FIG. 19 in that the first charge generation layer CGL1_1 may be physically separated from the second side surface of the bank BK (or the outer surface of the third part BK3) (see FIG. 7), and the second charge generation layer CGL2_1 of FIG. 19 may also be physically separated from the second side surface of the bank BK (or the outer surface of the third part BK3).

More specifically, a second opening OP2 may be formed between the physically separated second charge generation layers CGL2_1. Further, similar to FIG. 7, the first opening OP1 may be formed between the physically separated first charge generation layers CGL1_1. The second stack EL2 positioned on the first charge generation layer CGL1_1 may be in direct contact with the first stack EL1 through the first opening OP1. The third stack EL3 positioned on the second charge generation layer CGL2_1 may be in direct contact with the second stack EL2 through the second opening OP2. Since the contact relationship between the first opening OP1, the second stack EL2, and the first stack EL1 has been described above in FIG. 7, detailed description thereof will be omitted below.

Although the embodiments have been described above with reference to the accompanying drawings, those skilled in the art to which the present specification pertains will be able to understand that the above-described technical configuration can be carried out in other specific forms without changing the technical spirit or essential features thereof. Therefore, it should be understood that the above-described embodiments are illustrative and not restrictive in all respects. In addition, the scope of the embodiments is indicated by the claims to be described below rather than the detailed description. In addition, the meaning and scope of the claims and all changed or modified forms derived from the equivalent concept thereof should be construed as being included in the scope of the embodiments.

### DESCRIPTION OF REFERENCE NUMERALS

1: display device
2: substrate
3: insulating layer
4: first electrode
5: common emission layer
6: second electrode
7: capping layer
8: encapsulation layer
9: color filter layer
BK: bank

What is claimed is:

1. A display device comprising:
a substrate including a pixel, the pixel comprising a plurality of sub-pixels;
a first electrode in each of the plurality of sub-pixels; and
a bank between adjacent sub-pixels from the plurality of sub-pixels, the bank on the first electrode,
wherein the first electrode of a second sub-pixel among the plurality of sub-pixels is under the first electrode of a first sub-pixel, and the bank includes a plurality of side surfaces, and lengths between the plurality of side surfaces are different.

2. The display device of claim 1, further comprising:
an insulating layer between the substrate and the first electrode, the insulating layer including an indentation indented in a thickness direction in the second sub-pixel, and the first electrode of the second sub-pixel is positioned in the indentation.

3. The display device of claim 2, wherein the bank includes a first part, a second part connected to the first part and overlapping the first electrode of the first sub-pixel, and a third part connected to the first part and overlapping the first electrode of the second sub-pixel, and a portion of the first part is in the indentation.

4. The display device of claim 3, wherein a thickness of the third part is larger than a thickness of the second part.

5. The display device of claim 3, wherein a length of a side surface of the third part is larger than a length of a side surface of the second part.

6. The display device of claim 3, further comprising:
a common emission layer on an upper surface of the first electrode that is exposed by the bank.

7. The display device of claim 6, wherein the common emission layer includes a first stack, a first charge generation layer on the first stack, and a second stack on the first charge generation layer.

8. The display device of claim 7, wherein each of the first stack and the second stack includes a plurality of layers.

9. The display device of claim 8, wherein a thickness of the first charge generation layer is smaller than a thickness of each of the plurality of layers of the first stack and smaller than a thickness of each of the plurality of layers of the second stack.

10. The display device of claim 7, wherein a thickness of the first charge generation layer on a side surface of the second part is larger than a thickness of the first charge generation layer on a side surface of the third part and smaller than a thickness of the first charge generation layer on an upper surface of the first part.

11. The display device of claim 7, wherein the first charge generation layer is separated from a side surface of the third part.

12. The display device of claim 11, wherein the second stack is in direct contact with the first stack on the side surface of the third part.

13. The display device of claim 7, wherein the common emission layer further includes a second charge generation layer on the second stack, and a third stack on the second charge generation layer.

14. The display device of claim 1, wherein a height of a surface of the first electrode of the second sub-pixel is lower than a height of a surface of the first electrode of the first sub-pixel.

15. A display device comprising:
a substrate including a pixel, the pixel comprising a plurality of sub-pixels;
a first electrode in each of the plurality of sub-pixels;
a bank between adjacent sub-pixels from the plurality of sub-pixels on the first electrode; and
a common emission layer on an upper surface of the first electrode that is exposed by the bank,
wherein the bank has an asymmetric shape, and the common emission layer is separated from the bank with the asymmetric shape.

16. The display device of claim 15, wherein the bank includes a first part, a second part connected to the first part and overlapping the first electrode of a first sub-pixel among the plurality of sub-pixels, a third part connected to the first part and overlapping the first electrode of a second sub-pixel among the plurality of sub-pixels, and a length of a side surface of the third part is larger than a length of a side surface of the second part.

17. The display device of claim 16, wherein the common emission layer includes a first stack, a first charge generation layer on the first stack, and a second stack on the first charge generation layer.

18. The display device of claim 17, wherein the first stack and the second stack each includes a plurality of layers, and a thickness of the first charge generation layer is smaller than a thickness of each of the plurality of layers of the first stack and smaller than a thickness of each of the plurality of layers of the second stack.

19. The display device of claim 17, wherein a thickness of the first charge generation layer on a side surface of the second part is larger than a thickness of the first charge generation layer on a side surface of the third part and smaller than a thickness of the first charge generation layer on an upper surface of the first part.

20. The display device of claim 17, wherein the first charge generation layer is separated from a side surface of the third part, and the second stack is in direct contact with the first stack on the side surface of the third part.
